(19) United States
(12) Patent Application Publication
(10) Pub. No.: US 2026/0123396 A1
(43) Pub. Date: Apr. 30, 2026

(54) SEMICONDUCTOR STRUCTURE AND MANUFACTURING METHOD THEREOF

(71) Applicant: UNITED MICROELECTRONICS CORP., Hsin-Chu City (TW)

(72) Inventors: Chin-Chia Yang, Tainan City (TW); Da-Jun Lin, Kaohsiung City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/988,940

(22) Filed: Dec. 20, 2024

(30) Foreign Application Priority Data
Oct. 25, 2024 (TW) 113140689

(51) Int. Cl. H01L 23/532; H01L 23/00

(52) U.S. Cl. CPC H10W 20/47; H10W 72/244; H10W 72/90; H10W 72/923; H10W 72/9415; H10W 72/952

(57) ABSTRACT

A semiconductor structure includes a semiconductor substrate, pad structures, dielectric structures, a second dielectric layer, and a void. The semiconductor substrate includes a first dielectric layer, the pad structures and the dielectric structure are disposed on the first dielectric layer, and each dielectric structure is disposed on a sidewall of one of the pad structures. A top surface of each dielectric structure is lower than a top surface of each pad structure in a vertical direction. The first dielectric layer includes a recess located between two adjacent dielectric structures in a horizontal direction. The second dielectric layer covers the pad structures, the dielectric structures, and the first dielectric layer. The void is located in the second dielectric layer. At least a part of the void is sandwiched between two adjacent pad structures in the horizontal direction, and the void is located directly above the recess in the vertical direction.

### BACKGROUND OF THE INVENTION

### 1. Field of the Invention

The present invention relates to a semiconductor structure and a manufacturing method thereof, and more particularly, to a semiconductor structure including pad structures and a manufacturing method thereof.

### 2. Description of the Prior Art

The technology of semiconductor integrated circuits continues to improve, and the products of each new generation process have smaller and more complex circuit designs than that of the previous generation. The number and density of functional elements on each wafer region have to be continuously increased due to product innovation requirements, and of course the geometric dimensions of each element need to be smaller and smaller. Correspondingly, in the part of integrated circuit packaging technology, a packaging technology that occupies a smaller area than that of the previous packaging technology is also required to meet product requirements. In the wafer-to-wafer bonding technology, two or more than two semiconductor wafers may constitute a 3D integrated circuit (3D IC) by aligning and bonding, and the number of the elements within the limited occupied area may be increased accordingly.

### SUMMARY OF THE INVENTION

A semiconductor structure and a manufacturing method thereof are provided in the present invention. Dielectric structures are formed on sidewalls of pad structures, and a recess is formed in a first dielectric layer and located between the dielectric structures adjacent to each other for moving a void in a second dielectric layer downwards. Related issues generated by a void located too high may be improved, and the manufacturing yield may be enhanced accordingly.

According to an embodiment of the present invention, a semiconductor structure is provided. The semiconductor structure includes a semiconductor substrate, pad structures, dielectric structures, a second dielectric layer, and a void. The semiconductor substrate includes a first dielectric layer, and the pad structures and the dielectric structures are disposed on the first dielectric layer. Each of the dielectric structures is disposed on a sidewall of one of the pad structures, a top surface of each of the dielectric structures is lower than a top surface of each of the pad structures in a vertical direction, and the first dielectric layer includes a recess located between two of the dielectric structures adjacent to each other in a horizontal direction. The second dielectric layer covers the pad structures, the dielectric structures, and the first dielectric layer. The void is located in the second dielectric layer, at least a part of the void is sandwiched between two of the pad structures adjacent to each other in the horizontal direction, and the void is located directly above the recess in the vertical direction.

According to an embodiment of the present invention, a manufacturing method of a semiconductor structure is provided. The manufacturing method includes the following steps. A semiconductor substrate is provided, and the semiconductor substrate incudes a first dielectric layer. Pad structures are formed on the first dielectric layer. Dielectric structures are formed on the first dielectric layer, each of the dielectric structures is disposed on a sidewall of one of the pad structures, and a top surface of each of the dielectric structures is lower than a top surface of each of the pad structures in a vertical direction. A recess is formed in the first dielectric layer and located between two of the dielectric structures adjacent to each other in a horizontal direction. A second dielectric layer is formed covering the pad structures, the dielectric structures, and the first dielectric layer. A void is located in the second dielectric layer, at least a part of the void is sandwiched between two of the pad structures adjacent to each other in the horizontal direction, and the void is located directly above the recess in the vertical direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a semiconductor structure according to an embodiment of the present invention.

FIGS. 2-6 are schematic drawings illustrating a manufacturing method of a semiconductor structure according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, and FIG. 6 is a schematic drawing in a step subsequent to FIG. 5.

FIGS. 7-9 are schematic drawings illustrating a manufacturing method of a semiconductor structure according to another embodiment of the present invention, wherein FIG. 8 is a schematic drawing in a step subsequent to FIG. 7, and FIG. 9 is a schematic drawing in a step subsequent to FIG. 8.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

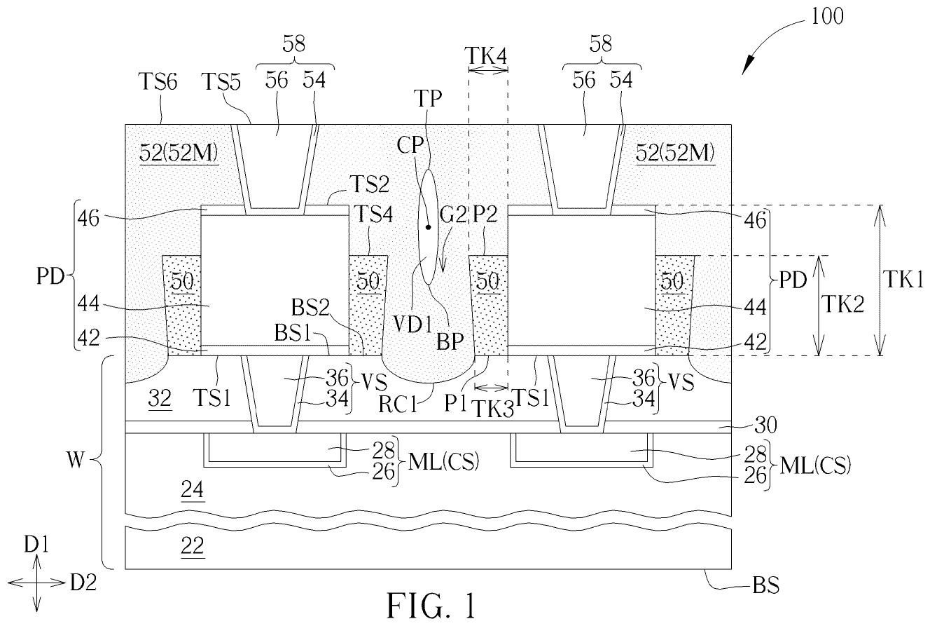

Please refer to FIG. 1. FIG. 1 is a schematic drawing illustrating a semiconductor structure 100 according to an embodiment of the present invention. As shown in FIG. 1, the semiconductor structure 100 includes a semiconductor substrate W, a plurality of pad structures PD, a plurality of dielectric structures 50, a second dielectric layer 52, and a void VD1. The semiconductor substrate W includes a first dielectric layer 32. The pad structures PD and the dielectric structures 50 are disposed on the first dielectric layer 32. Each of the dielectric structures 50 is disposed on a sidewall of one of the pad structures PD. A top surface TS4 of each of the dielectric structures 50 is lower than a top surface TS2 of each of the pad structures PD in a vertical direction D1, and the first dielectric layer 32 includes a recess RC1 located between two of the dielectric structures 50 adjacent to each other in a horizontal direction D2. The second dielectric layer 52 covers the pad structures PD, the dielectric structures 50, and the first dielectric layer 32. The void VD1 is located in the second dielectric layer 52, at least a part of the void VD1 is sandwiched between two of the pad structures PD adjacent to each other in the horizontal direction D2, and the void VD1 is located directly above the recess RC1 in the vertical direction D1. By the formation of the dielectric structures 50 and the recess RC1 located in the first dielectric layer 32, the location of the void VD1 formed in the second dielectric layer 52 may be moved downwards for avoiding negative influence of the void VD1 located too high on other related manufacturing processes.

In some embodiments, the vertical direction D1 may be regarded as a thickness direction of the semiconductor substrate W. The semiconductor substrate W may have a top surface (such as a top surface TS1 of the first dielectric layer) and a bottom surface BS opposite to the top surface in the vertical direction D1, and the pad structures PD, the dielectric structures 50, the second dielectric layer 52, and the void VD1 described above may be disposed at the side of the top surface. A horizontal direction substantially orthogonal to the vertical direction D1 (such as the horizontal direction D2 and other direction orthogonal to the vertical direction D1) may be substantially parallel with the top surface and/or the bottom surface BS of the semiconductor substrate W, but not limited thereto. In this description, a distance between the bottom surface BS of the semiconductor substrate W and a relatively higher location and/or a relatively higher part in the vertical direction D1 may be greater than a distance between the bottom surface BS of the semiconductor substrate W and a relatively lower location and/or a relatively lower part in the vertical direction D1. The bottom or a lower portion of each component may be closer to the bottom surface BS of the semiconductor substrate W in the vertical direction D1 than the top or upper portion of this component. Another component disposed above a specific component may be regarded as being relatively far from the bottom surface BS of the substrate W in the vertical direction D1, and another component disposed under a specific component may be regarded as being relatively close to the bottom surface BS of the substrate W in the vertical direction D1. Additionally, in this description, a top surface and a top portion of a specific component may include the topmost surface and the topmost portion of this component in the vertical direction D1, respectively, and a bottom surface and a bottom portion of a specific component may include the bottommost surface and the bottommost portion of this component in the vertical direction D1, respectively. In this description, the condition that a certain component is disposed between two other components in a specific direction may include but is not limited to a condition that the certain component is sandwiched between the two other components in the specific direction.

In some embodiments, the semiconductor substrate W may include a substrate 22, a dielectric layer 24, an interconnection structure CS, a dielectric layer 30, the first dielectric layer 32, and via conductors VS. The substrate 22 may include a silicon substrate or a substrate made of other suitable semiconductor materials or non-semiconductor materials. The dielectric layer 24 is disposed on the substrate 22, the interconnection structure CS is disposed in the dielectric layer 24, the first dielectric layer 32 is disposed above the dielectric layer 24 and the interconnection structure CS, and the dielectric layer 30 is disposed between the first dielectric layer 32 and the dielectric layer 24. The first dielectric layer 32 and the second dielectric layer 52 may respectively include an oxide dielectric material (such as silicon oxide) or other suitable dielectric materials, and the dielectric layer 30 and the dielectric layer 24 may respectively include a nitride dielectric material (such as silicon nitride), a carbide dielectric material (such as silicon carbide), a low dielectric constant (low-k) dielectric material (such as a dielectric material having dielectric constant lower than 2.7, but not limited thereto), or other suitable dielectric materials. The interconnection structure CS may include a plurality of electrically conductive lines (such as electrically conductive lines ML) and a plurality of via conductors (not illustrated) alternately disposed in the vertical direction D1 for forming the required connection paths. In some embodiments, the electrically conductive line ML may be regarded as the electrically conductive line located at the topmost layer in the interconnection structure CS, the via conductor VS may penetrate through the first dielectric layer 32 and the dielectric layer 30, and each of the pad structures PD may be electrically connected with the interconnection structure CS through the corresponding via conductor VS.

In some embodiments, some active components (such as transistors, diodes and so forth), passive components (such as capacitors, resistors and so forth), and/or other related circuits may be disposed on the substrate 22, and the pad structures PD may be electrically connected to the components and/or the circuits on the substrate 22 via the interconnection structure CS. In some embodiments, the semiconductor substrate W may be regarded as a wafer including integrated circuits, and the pad structures PD may be regarded as the metal electrically conductive structures formed on the wafer for bonding the semiconductor structure 100 to other wafers and forming a 3D integrated circuit (3D IC), but not limited thereto. In addition, the thickness of the pad structure PD may be apparently greater than that of the electrically conductive line ML. For example, a thickness TK1 of the pad structure PD may be about 8,000 angstroms, but not limited thereto. In some embodiments, the electrically conductive line ML may include a barrier layer 26 and an electrically conductive material 28 disposed on the barrier layer 26, the via conductor VS may include a barrier layer 34 and an electrically conductive material 36 disposed on the barrier layer 34, and each of the pad structures PD may include a barrier layer 42, a barrier layer 46, and an electrically conductive layer 44 disposed between the barrier layer 42 and the barrier layer 46, but not limited thereto. The barrier layer 26, the barrier layer 34, the barrier layer 42, and the barrier layer 46 may include titanium, titanium nitride, tantalum, tantalum nitride, or other suitable electrically conductive barrier materials. The electrically conductive material 28, the electrically conductive material 36, and the electrically conductive layer 44 may respectively include a material with relatively low electrical resistivity, such as copper, aluminum, tungsten and so forth.

In some embodiments, the semiconductor structure 100 may further include connection structures 58 disposed on the pad structures PD, each of the connection structures 58 may penetrate through the second dielectric layer 52 located above one of the pad structures PD in the vertical direction PD and may be directly connected with and electrically connected with the one of the pad structures PD, and the void VD1 may be lower than a top surface TS5 of each of the connection structures 58 in the vertical direction D1. In some embodiments, because of the influence of related processes, the top surface TS5 of each of the connection structures 58 and a top surface TS6 of the second dielectric layer 52 may be substantially coplanar, but not limited thereto. Each of the connection structures 58 may include a barrier layer 54 and an electrically conductive material 56 disposed on the barrier layer 54. The barrier layer 54 may include titanium, titanium nitride, tantalum, tantalum nitride, or other suitable electrically conductive barrier materials. The electrically conductive material 56 may include a material with relatively low electrical resistivity, such as copper, aluminum, tungsten and so forth. In some embodiments, the barrier layer 46 located on the electrically conductive layer 44 may be regarded as an etching stop layer, such as a layer for providing an etching stop effect in the process of forming openings corresponding to the connection structures 58, and each of the connection structures 58 may further penetrate through the etching stop layer (i.e. the barrier layer 46) of one of the pad structures PD in the vertical direction D1 for directly contacting the electrically conductive layer 44 in the corresponding pad structure PD, but not limited thereto.

Each of the pad structures PD and each of the dielectric structures 50 may be disposed on the top surface TS1 of the first dielectric layer 32 and directly connected with the first dielectric layer 32, and a bottom surface BS1 of the pad structure PD and a bottom surface BS2 of the dielectric structure 50 may be substantially coplanar, but not limited thereto. Each of the dielectric structures 50 may directly cover and contact the sidewall of the barrier layer 42 and the sidewall of the electrically conductive layer 44 in the corresponding pad structure PD, and a thickness TK2 of each of the dielectric structures 50 in the vertical direction D1 (such as a distance between the top surface TS4 and the bottom surface BS2 in the vertical direction D1) may be less than a thickness TK1 of each of the pad structures PD in the vertical direction D1 (such as a distance between the top surface TS2 and the bottom surface BS1 in the vertical direction D1). In some embodiments, the thickness TK2 may range from 0.4 times the thickness TK1 to 0.7 times the thickness TK1 substantially for moving the position wherein the void VD1 is formed downwards and still providing a specific protection effect to the pad structures PD. In addition, because of related process characteristics, a thickness TK4 of an upper portion P2 of each of the dielectric structures 50 in the horizontal direction D2 may be greater than a thickness TK3 of a lower portion P1 of each of the dielectric structures 50 in the horizontal direction D2. The thickness TK3 and the thickness TK4 may also be regarded as a length and/or a width of the lower portion P1 in the horizontal direction D2 and a length and/or a width of the upper portion P2 in the horizontal direction D2, respectively, and each of the dielectric structures 50 may include a structure that is wide at the top and narrow at the bottom. A material composition of the dielectric structures 50 may be different from a material composition of the first dielectric layer 32 and a material composition of the second dielectric layer 52, and a material of the dielectric structures 50 may include silicon carbonitride, silicon nitride, or other suitable dielectric materials. The recess RC1 may include a concave surface lower than a top surface of the first dielectric layer 32 located under each of the dielectric structures 50 in the vertical direction D1 and/or a top surface of the first dielectric layer 32 located under each of the pad structures PD in the vertical direction D1 (such as the top surface TS1). Apart of the second dielectric layer 52 may be disposed in the recess RC1 and sandwiched between the void VD1 and the recess RC1 in the vertical direction D1. The second dielectric layer 52 may be directly connected with each of the connection structures 58, each of the pad structures PD, each of the dielectric structures 50, the first dielectric layer 32, and the recess RC1.

In some embodiments, the void VD1 may be surrounded by the second dielectric layer 52 and is not directly connected with the connection structures 58, the pad structures PD, the dielectric structures 50, and the first dielectric layer 32. At least a part of the void VD1 may be sandwiched between two of the dielectric structures 50 adjacent to each other in the horizontal direction D2, a bottom end BP of the void VD1 may be lower than the top surface TS4 of each of the dielectric structures 50 in the vertical direction D1, and a top end TP of the void VD1 may be higher than the top surface TS2 of each of the pad structures PD in the vertical direction D1 and lower than the top surface TS5 of each of the connection structures 58 and the top surface TS6 of the second dielectric layer 52 in the vertical direction D1, but not limited thereto. In addition, a center point CP of the void VD1 in the vertical direction D1 may be lower than the top surface TS2 of each of the pad structures PD or coplanar with the top surface TS2, and a distance between the top end TP of the void VD1 and the top surface TS2 of each of the pad structures PD in the vertical direction D1 may substantially range from one third of a length of the void VD1 in the vertical direction D1 to one-half of the length of the void VD1 in the vertical direction D1, but not limited thereto. The shape of the void VD1 may include but is not limited to the condition illustrated in FIG. 1, and the void VD1 may include a seam and/or an air gap generated by the process of forming the second dielectric layer 52, but not limited thereto.

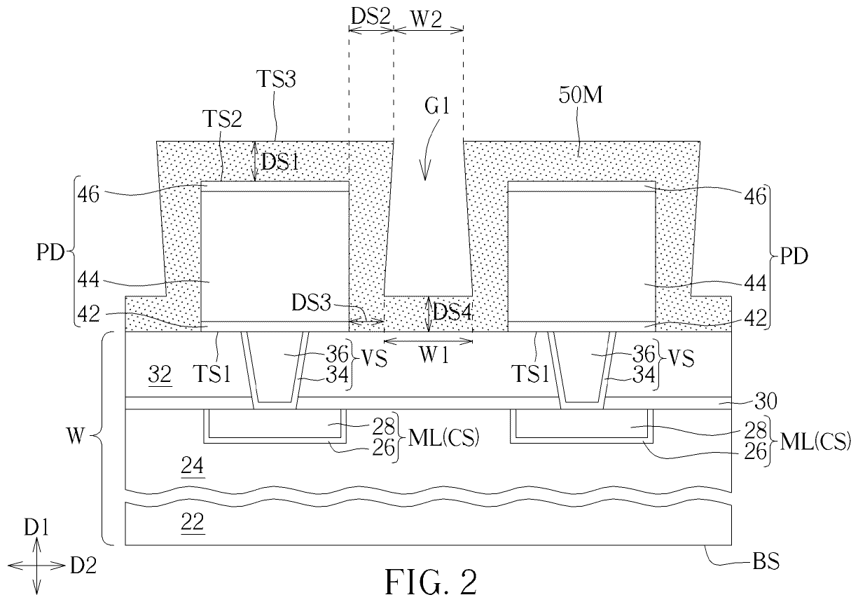

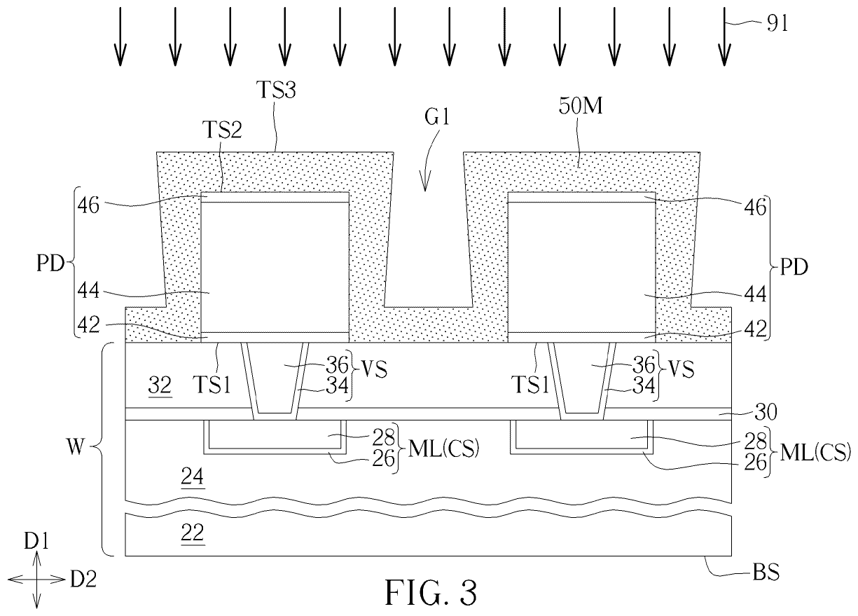

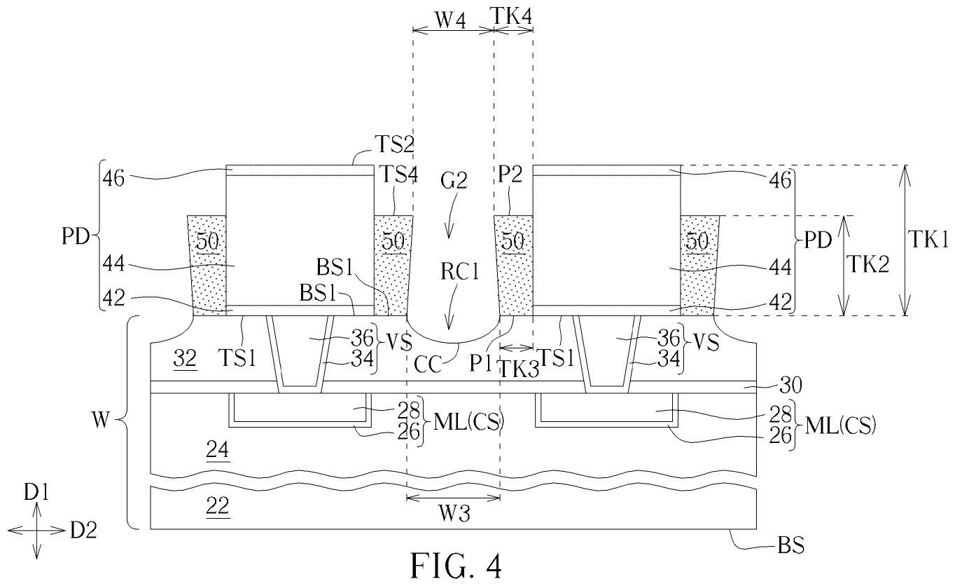

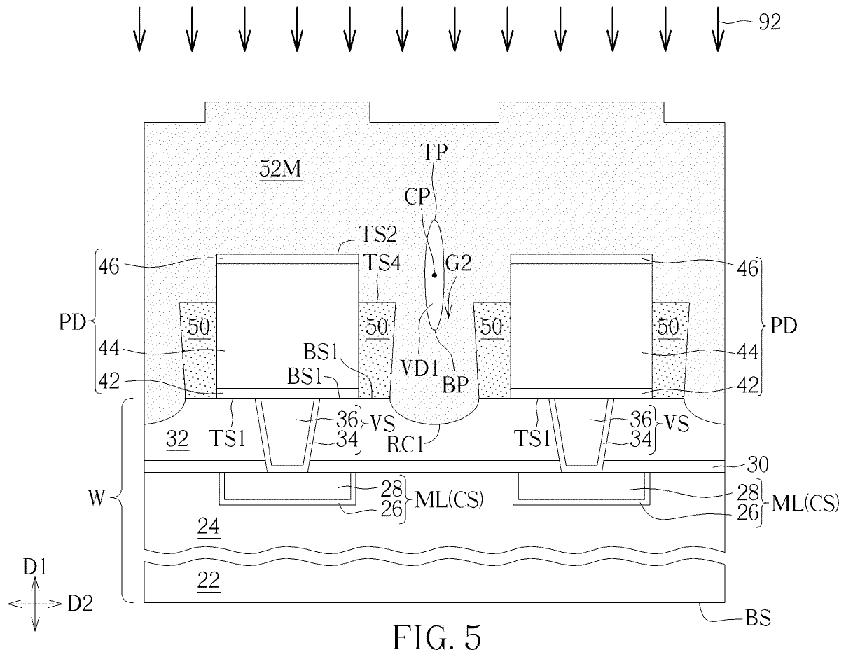

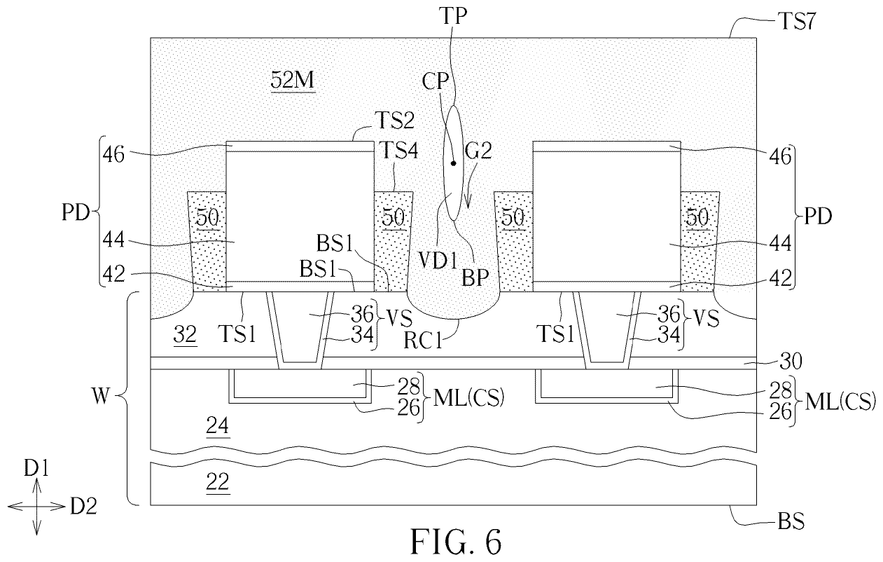

Please refer to FIGS. 1-6. FIGS. 2-6 are schematic drawings illustrating a manufacturing method of a semiconductor structure according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, and FIG. 6 is a schematic drawing in a step subsequent to FIG. 5. In some embodiments, FIG. 1 may be regarded as a schematic drawing in a step subsequent to FIG. 6, but not limited thereto. As shown in FIG. 1, the manufacturing method in this embodiment includes the following steps. Firstly, the semiconductor substrate W is provided, and the semiconductor substrate W incudes the first dielectric layer 32. The pad structures PD and the dielectric structures 50 are formed on the first dielectric layer 32, and each of the dielectric structures 50 is disposed on the sidewall of one of the pad structures PD. The top surface TS4 of each of the dielectric structures 50 is lower than the top surface TS2 of each of the pad structures PD in the vertical direction D1. The recess RC1 is formed in the first dielectric layer 32 and located between two of the dielectric structures 50 adjacent to each other in the horizontal direction D2. Subsequently, the second dielectric layer 52 is formed covering the pad structures PD, the dielectric structures 50, and the first dielectric layer 32. The void VD1 is located in the second dielectric layer 32, at least a part of the void VD1 is sandwiched between two of the pad structures PD adjacent to each other in the horizontal direction D2, and the void VD1 is located directly above the recess RC1 in the vertical direction D1.

Specifically, the manufacturing method in this embodiment may include but is not limited to the following steps. As shown in FIG. 2, the pad structures PD may be formed on the semiconductor substrate W, and each of the pad structures PD may include the barrier layer 42, the electrically conductive layer 44, and the barrier layer 46 described above, but not limited thereto. Subsequently, a dielectric cap layer 50M may be formed covering the pad structures PD and the first dielectric layer 32. The space between two of the pad structures PD adjacent to each other is not fully filled with the dielectric cap layer 50M, and a first gap G1 may be located between two of the pad structures PD adjacent to each other in the horizontal direction D2 and surrounded by the dielectric cap layer 50M in the horizontal direction D2. Because of the influence of the thickness of the pad structure PD and/or the characteristics of the process of forming the dielectric cap layer 50M (such as a chemical vapor deposition process), a top width (such as a width W2) of the first gap G1 defined by the dielectric cap layer 50M may be less than a bottom width (such as a width W1) of the first gap G1, and at least a part of the dielectric cap layer 50M covering each of the pad structures PD may include a structure that is wide at the top and narrow at the bottom. For example, a width of the first gap G1 (may also be regarded as a length of the first gap G1 in the horizontal direction D2) may gradually and/or continuously increase from the topmost end of the first gap G1 in the vertical direction D1 to the bottommost end of the first gap G1 in the vertical direction D1, a distance DS2 between the edge of the topmost end of the first gap G1 in the vertical direction D1 and the pad structure PD in the horizontal direction D2 may be greater than the thickness of the dielectric cap layer 50M located above the pad structure PD in the vertical direction D1 (such as a distance DS1 between a top surface TS3 of the dielectric cap layer 50M and the top surface TS2 of the pad structure PD in the vertical direction D1), a distance between the edge of the bottommost end of the first gap G1 in the vertical direction D1 and the pad structure PD in the horizontal direction D2 may be less than the distance DS1, and a distance DS4 between the bottommost end of the first gap G1 and the first dielectric layer 32 may be less than the distance DS1, but not limited thereto. In some embodiments, the distance DS2 may range from 1.1 times the distance DS1 to 1.3 times the distance DS1, the distance DS3 and the distance DS4 may respectively range from 0.6 times the distance DS1 to 0.9 times the distance DS1, and a distance between two of the pad structures PD adjacent to each other in the horizontal direction D2 may be about 2.4 micrometers, but not limited thereto.

Subsequently, as shown in FIG. 3 and FIG. 4, an etching back process 91 may be performed to the dielectric cap layer 50M, and the dielectric cap layer 50M may be etched to be the dielectric structures 50 described above by the etching back process 91. Therefore, a material composition of the dielectric cap layer 50M may be different from the material composition of the first dielectric layer 32 and the material composition of the second dielectric layer, and a material of the dielectric cap layer 50M may include silicon carbonitride, silicon nitride, or other suitable dielectric materials. In addition, a part of the first dielectric layer 32 may be removed by the etching back process 91, and the recess RC1 may be formed by the etching back process 91. In other words, the recess RC1 and the dielectric structures 50 may be formed concurrently by the etching back process 91. Additionally, after the etching back process 91, a second gap G2 may be located between two of the dielectric structures 50 adjacent to each other in the horizontal direction D2, and the second gap G2 may be directly connected with the recess RC1. A top width (such as a width W4) of the second gap G2 may be greater than the top width (such as the width W2) of the first gap G2, and a bottom width (such as a width W3) of the second gap G2 may be greater than the bottom width (such as the width W1) of the first gap G1. In other words, the etching back process 91 may be used to form the recess RC1 and convert the first gap G1 into the second gap G2 with the wider top portion for allowing the void subsequently formed in the second dielectric layer to move downwards more easily. In addition, the recess RC1 may include a concave surface CC lower than the top surface TS1 of the first dielectric layer 32 located under each of the dielectric structures 50 in the vertical direction D1 and/or located under each of the pad structures PD in the vertical direction D1, and a depth of the recess RC1 (such as a distance between the bottommost part of the concave surface CC and the top surface TS1 in the vertical direction D1) may be substantially equal to or greater than the distance DS1 between the top surface TS3 of the dielectric cap layer 50M and the top surface TS2 of the pad structure PD in the vertical direction D1 before the etching back process 91, but not limited thereto. It is worth noting that the method of forming the dielectric structures 50 in the present invention may include but is not limited to the steps shown in FIGS. 2-4, and the dielectric structures 50 and the recess RC1 may be formed by other suitable approaches according to some design considerations.

As shown in FIG. 5, after the dielectric structures 50 and the recess RC1 are formed, a dielectric material 52M may be formed covering the pad structures PD, the dielectric structures 50, and the first dielectric layer 32, and a part of the dielectric material 52M may be formed in the recess RC1. Because of the influence of the thickness of the pad structure PD, the dielectric structures 50, and/or the process of forming the dielectric material 52M (such as a chemical vapor deposition process), the void VD1 may be formed in the dielectric material 52M. In some embodiments, at least a part of the void VD1 may be formed in the second gap G2, and at least a part of the void VD1 may be sandwiched between the dielectric structures 50 adjacent to each other in the horizontal direction D2 accordingly, but not limited thereto. It is worth noting that the location where the void VD1 is formed may be modified by controlling the thickness of the dielectric structure 50 and/or the depth of the recess RC1. However, because a certain thickness of the dielectric structure 50 is still required and the depth of the recess RC1 is limited to the thickness of the first dielectric layer 32, the top end TP of the void VD1 may be still higher than the top surface TS2 of each of the pad structures PD in the vertical direction D1 accordingly, and the distance between the top end TP and the top surface TS2 in the vertical direction D1 may substantially range from one third of the length of the void VD1 in the vertical direction D1 to one-half of the length of the void VD1 in the vertical direction D1, but not limited thereto.

Subsequently, as shown in FIG. 5 and FIG. 6, a planarization process 92 may be performed to the dielectric material 52M for planarizing the top surface of the dielectric material 52M. The planarization process 92 may include chemical mechanical polishing process or other suitable planarization approaches. The location wherein the void VD1 is formed may be moved downwards relatively by the dielectric structures 50 and the recess RC1 for preventing the void VD1 from being exposed in the planarization process 92 and influencing subsequent processes, and the manufacturing yield may be enhanced accordingly. In other words, the void VD1 is formed in the dielectric material 52M before the planarization process, and the void VD1 is lower than a top surface TS7 of the dielectric material 52M in the vertical direction D1 after the planarization process 92. As shown in FIG. 5, FIG. 6, and FIG. 1, after the planarization process 92, the connection structures 58 may be formed, and the dielectric material 52M may become the second dielectric layer 52 after the connection structures 58 are formed. Each of the connection structures 58 penetrates through the second dielectric layer 52 located above one of the pad structures PD in the vertical direction and is directly connected with the one of the pad structures PD, and the void VD1 is lower than the top surface TS5 of each of the connection structures 58 in the vertical direction D1.

In some embodiments, a method of forming the connection structures 58 may include but is not limited to the following steps. Firstly, openings corresponding to the connection structures 58 may be formed, each of the openings may penetrate through the dielectric material 52M located above the corresponding pad structure PD and the barrier layer 46 in the corresponding pad structure PD in the vertical direction D1, and the barrier layer 46 may be used to provide an etching stop effect in an etching process of forming the openings, but not limited thereto. Subsequently, the barrier layer 54 and the electrically conductive material 56 may be formed, and the openings may be filled with the barrier layer 54 and the electrically conductive material 56. Another planarization process (such as a chemical mechanical polishing process, but not limited thereto) may then be performed for removing the barrier layer 54 and the electrically conductive material 56 located outside the openings and forming the connection structures 58. In some embodiments, a part of the dielectric material 52M may be removed by the planarization process described above, the dielectric material 52M after the planarization process may become the second dielectric layer 52, and the top surface TS6 of the second dielectric layer 52 and the top surface TS5 of the connection structure 58 may be substantially coplanar accordingly, but not limited thereto. In addition, the method of forming the second dielectric layer 52 may include but is not limited to the steps shown in FIG. 5, FIG. 6, and FIG. 1. The location where the void VD1 is formed may be controlled by the dielectric structures 50 and the recess RC1 for keeping the barrier layer 54 and the electrically conductive material 56 from being formed in the void VD1 and avoiding metal residue issue, and the related manufacturing yield may be enhanced accordingly.

The following description will detail the different embodiments of the present invention. To simplify the description, the following description will detail the dissimilarities among different embodiments and the identical features will not be redundantly described. In addition, identical components in each of the following embodiments are marked with identical symbols for making it easier to understand the differences between the embodiments.

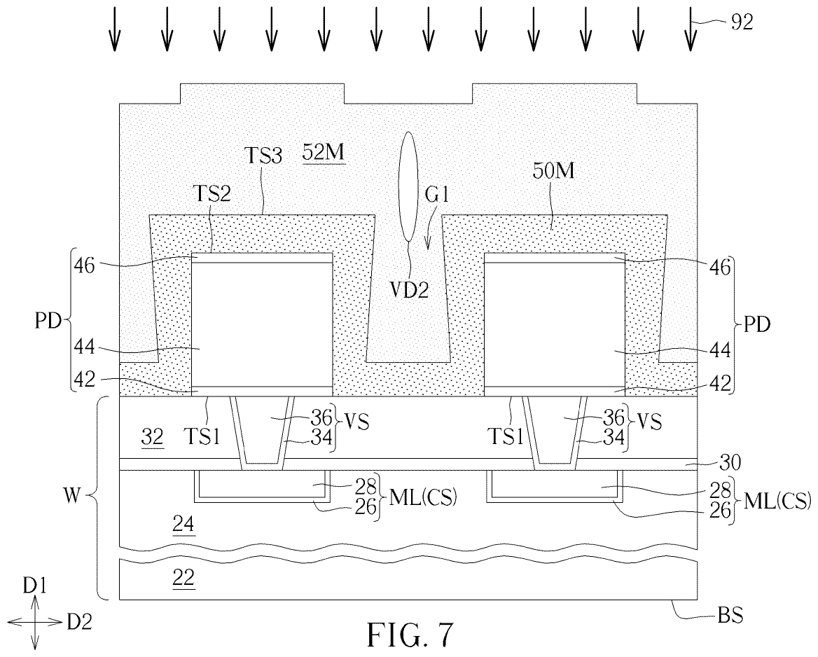

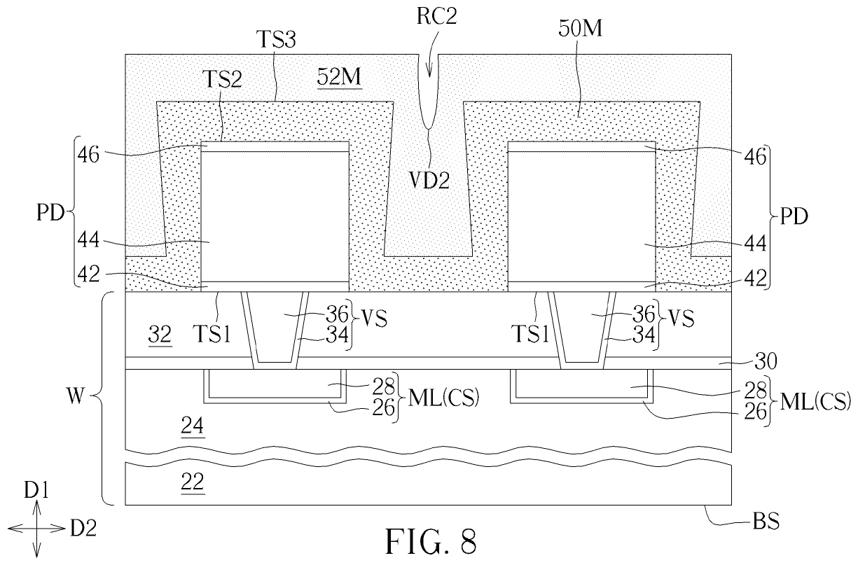

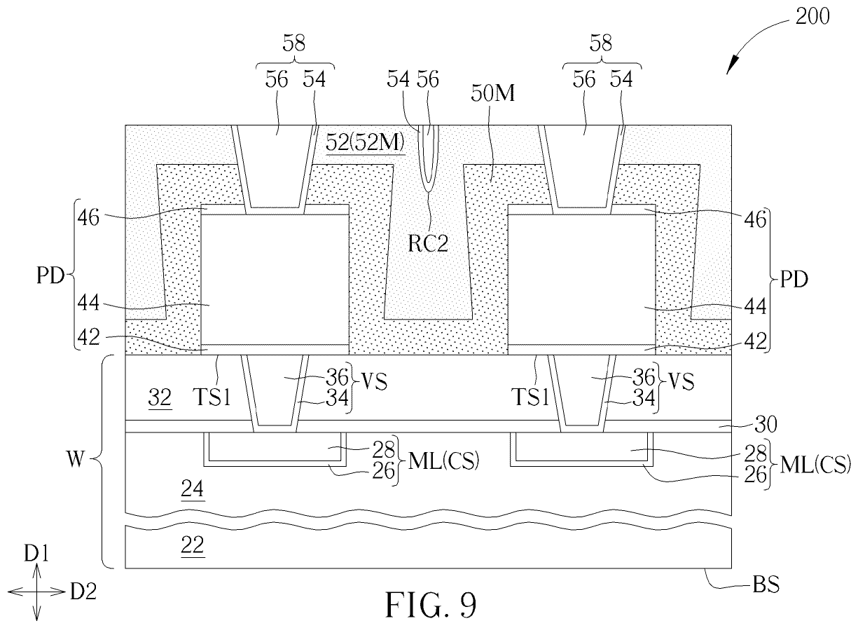

Please refer to FIGS. 7-9. FIGS. 7-9 are schematic drawings illustrating a manufacturing method of a semiconductor structure 200 according to another embodiment of the present invention, wherein FIG. 8 is a schematic drawing in a step subsequent to FIG. 7, and FIG. 9 is a schematic drawing in a step subsequent to FIG. 8. As shown in FIG. 7, in this embodiment, the dielectric cap layer 50M is not processed by the etching back process, and the dielectric structures described in the above embodiment are not formed in this embodiment accordingly. The dielectric material 52M is formed after the dielectric cap layer 50M is formed. A location where a void VD2 is formed in the dielectric material 52M will be relatively high because of the influence of the narrow top portion of the first gap G1, and a lower portion of the void VD2 may be formed in the first gap G1. As shown in FIG. 7 and FIG. 8, after the planarization process 92 is performed to the dielectric material 52M, the void VD2 may be exposed by the planarization process 92 easily and become a recess RC2 because the location of the void VD2 is relatively high. As shown in FIGS. 8-9, when the recess RC2 is formed, the recess RC2 may be filled with the barrier layer 54 and/or the electrically conductive material 56 and metal residue may be generated in the process of forming the connection structures 58. The metal residue in the recess RC2 may influence the operation of the semiconductor structure 200 and/or the condition of other subsequent processes performed to the semiconductor structure 200 (such as being bonded and stacked with other wafers, but not limited thereto).

To summarize the above descriptions, according to the semiconductor structure and the manufacturing method thereof in the present invention, the location of the void formed in the second dielectric layer may be controlled by the dielectric structures and the recess located in the first dielectric layer for avoiding negative influence of the void located too high on other related manufacturing processes, and the related manufacturing yield may be enhanced accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a semiconductor substrate comprising a first dielectric layer;
pad structures disposed on the first dielectric layer;
dielectric structures disposed on the first dielectric layer, wherein each of the dielectric structures is disposed on a sidewall of one of the pad structures, a top surface of each of the dielectric structures is lower than a top surface of each of the pad structures in a vertical direction, and the first dielectric layer comprises a recess located between two of the dielectric structures adjacent to each other in a horizontal direction;
a second dielectric layer covering the pad structures, the dielectric structures, and the first dielectric layer; and
a void located in the second dielectric layer, wherein at least a part of the void is sandwiched between two of the pad structures adjacent to each other in the horizontal direction, and the void is located directly above the recess in the vertical direction.

2. The semiconductor structure according to claim 1, wherein the recess comprises a concave surface lower than a top surface of the first dielectric layer located under the dielectric structures in the vertical direction.

3. The semiconductor structure according to claim 1, wherein a thickness of an upper portion of each of the dielectric structures in the horizontal direction is greater than a thickness of a lower portion of each of the dielectric structures in the horizontal direction.

4. The semiconductor structure according to claim 1, wherein each of the pad structures and each of the dielectric structures are directly connected with the first dielectric layer, and the second dielectric layer is directly connected with the first dielectric layer, each of the pad structures and each of the dielectric structures.

5. The semiconductor structure according to claim 1, wherein a thickness of each of the dielectric structures in the vertical direction is less than a thickness of each of the pad structures in the vertical direction.

6. The semiconductor structure according to claim 1, wherein at least a part of the void is sandwiched between the two of the dielectric structures adjacent to each other in the horizontal direction.

7. The semiconductor structure according to claim 1, wherein a material composition of the dielectric structures is different from a material composition of the first dielectric layer and a material composition of the second dielectric layer.

8. The semiconductor structure according to claim 1, wherein a material of the dielectric structures comprises silicon carbonitride or silicon nitride.

9. The semiconductor structure according to claim 1, further comprising:
connection structures disposed on the pad structures, wherein each of the connection structures penetrates through the second dielectric layer located above one of the pad structures in the vertical direction and is directly connected with the one of the pad structures, and the void is lower than a top surface of each of the connection structures in the vertical direction.

10. The semiconductor structure according to claim 9, wherein each of the pad structures comprises an electrically conductive layer and an etching stop layer disposed on the electrically conductive layer, and each of the connection structures further penetrates through the etching stop layer of one of the pad structures in the vertical direction.

11. A manufacturing method of a semiconductor structure, comprising:
providing a semiconductor substrate comprising a first dielectric layer;
forming pad structures on the first dielectric layer;
forming dielectric structures on the first dielectric layer, wherein each of the dielectric structures is disposed on a sidewall of one of the pad structures, a top surface of each of the dielectric structures is lower than a top surface of each of the pad structures in a vertical direction, and a recess is formed in the first dielectric layer and located between two of the dielectric structures adjacent to each other in a horizontal direction; and
forming a second dielectric layer covering the pad structures, the dielectric structures, and the first dielectric layer, wherein a void is located in the second dielectric layer, at least a part of the void is sandwiched between two of the pad structures adjacent to each other in the horizontal direction, and the void is located directly above the recess in the vertical direction.

12. The manufacturing method of the semiconductor structure according to claim 11, wherein a method of forming the dielectric structures comprises:
forming a dielectric cap layer covering the pad structures and the first dielectric layer, wherein a first gap is located between two of the pad structures adjacent to each other in the horizontal direction and surrounded by the dielectric cap layer in the horizontal direction; and
performing an etching back process to the dielectric cap layer, wherein the dielectric cap layer is etched to be the dielectric structures by the etching back process.

13. The manufacturing method of the semiconductor structure according to claim 12, wherein a material composition of the dielectric cap layer is different from a material composition of the first dielectric layer and a material composition of the second dielectric layer.

14. The manufacturing method of the semiconductor structure according to claim 12, wherein a material of the dielectric cap layer comprises silicon carbonitride or silicon nitride.

15. The manufacturing method of the semiconductor structure according to claim 12, wherein a part of the first dielectric layer is removed by the etching back process, and the recess is formed by the etching back process.

16. The manufacturing method of the semiconductor structure according to claim 12, wherein a top width of the first gap is less than a bottom width of the first gap.

17. The manufacturing method of the semiconductor structure according to claim 12, wherein a second gap is located between two of the dielectric structures adjacent to each other in the horizontal direction after the etching back process, a top width of the second gap is greater than a top width of the first gap, and a bottom width of the second gap is greater than a bottom width of the first gap.

18. The manufacturing method of the semiconductor structure according to claim 17, wherein at least a part of the void is formed in the second gap.

19. The manufacturing method of the semiconductor structure according to claim 11, wherein a method of forming the second dielectric layer comprises:
forming a dielectric material covering the pad structures, the dielectric structures, and the first dielectric layer; and
performing a planarization process to the dielectric material, wherein the void is formed in the dielectric material before the planarization process, and the void is lower than a top surface of the dielectric material in the vertical direction after the planarization process.

20. The manufacturing method of the semiconductor structure according to claim 19, further comprising:
forming connection structures after the planarization process, wherein the dielectric material becomes the second dielectric layer after the connection structures are formed, each of the connection structures penetrates through the second dielectric layer located above one of the pad structures in the vertical direction and is directly connected with the one of the pad structures, and the void is lower than a top surface of each of the connection structures in the vertical direction.
